(19) United States
(12) Patent Application Publication
(10) Pub. No.: US 2022/0307772 A1
(43) Pub. Date: Sep. 29, 2022

(54) COOLING DEVICE

(71) Applicant: FUJITSU LIMITED, Kawasaki-shi (JP)

(72) Inventors: KENJI SASABE, Kawasaki (JP); Hideo Kubo, Kawasaki (JP); Keita Hirai, Kawasaki (JP); KENTO OHGA, Yokohama (JP); Masahide KODAMA, Kawasaki (JP); ATSUSHI ENDO, Kawasaki (JP); Takashi Urai, Kawasaki (JP); Nobumitsu Aoki, Kawasaki (JP)

(73) Assignee: FUJITSU LIMITED, Kawasaki-shi (JP)

(21) Appl. No.: 17/540,279

(22) Filed: Dec. 2, 2021

(30) Foreign Application Priority Data
Mar. 26, 2021 (JP) 2021-054182

(51) Int. Cl. F28D 15/04

(52) U.S. Cl. CPC F28D 15/043; F28D 15/046

(57) ABSTRACT

A cooling device including: a container in which a refrigerant is sealed; a plurality of evaporation structures that evaporate the refrigerant in a liquid phase inside the container by heat reception; a plurality of condensation structures each of which is provided in corresponding one of the plurality of evaporation units and which condenses the refrigerant in a gas phase inside the container by heat radiation; a transport structure that transports the refrigerant in the liquid phase from the condensation units to the evaporation units by surface tension; and a movement portion that communicates the plurality of condensation units such that the refrigerant in the liquid phase is movable between the plurality of condensation structures.

### CROSS-REFERENCE TO RELATED APPLICATION

This application is based upon and claims the benefit of priority of the prior Japanese Patent Application No. 2021-54182, filed on Mar. 26, 2021, the entire contents of which are incorporated herein by reference.

### FIELD

The embodiments discussed herein are related to a cooling device.

### BACKGROUND

There is a cooling device including a condenser that condenses a gas refrigerant guided from an evaporator and a liquid return pipe that extends from the condenser to the evaporator with a downward gradient and returns a liquid refrigerant condensed by the condenser to the evaporator. In this cooling device, the shape of an opening end of the liquid return pipe in the evaporator is an oblique inclined end surface so that an opening faces upward, and the opening end is provided at a lower position than an end of a heat radiation fin.

Furthermore, there is a flat heat pipe having a structure in which a flat container is formed by pressing and deforming a groove pipe having grooves on an entire inner wall surface. In this structure, a wick material is arranged between facing upper and lower plates of the container, and is deformed corresponding to the container. In addition, an outer surface of the wick material is in contact with protrusions forming the grooves of the inner wall, and a passage for fluid movement is provided inside the wick material.

Examples of the related art include as follows: Japanese Laid-open Patent Publication No. 6-177296; and Japanese Laid-open Patent Publication No. 2004-198096.

### SUMMARY

According to an aspect of the embodiments, there is provided a cooling device including: a container in which a refrigerant is sealed; a plurality of evaporation structures that evaporate the refrigerant in a liquid phase inside the container by heat reception; a plurality of condensation structures each of which is provided in corresponding one of the plurality of evaporation units and which condenses the refrigerant in a gas phase inside the container by heat radiation; a transport structure that transports the refrigerant in the liquid phase from the condensation units to the evaporation units by surface tension; and a movement portion that communicates the plurality of condensation units such that the refrigerant in the liquid phase is movable between the plurality of condensation structures.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a perspective view illustrating a cooling device of a first embodiment;

FIG. 2 is an exploded perspective view illustrating the cooling device of the first embodiment;

FIG. 3 is a partial plan view illustrating an electronic device including the cooling device of the first embodiment together with an internal structure of the cooling device;

FIG. 4 is a plan view illustrating the internal structure of the cooling device of the first embodiment;

FIG. 5 is a cross-sectional view taken along a line 5-5 of FIG. 4, illustrating the cooling device of the first embodiment in a non-inclined state;

FIG. 6 is a cross-sectional view illustrating the cooling device of the first embodiment in an inclined state;

FIG. 7 is a plan view illustrating one end portions of transport pipes in the cooling device of the first embodiment together with a part of an evaporation unit;

FIG. 8A is a cross-sectional view illustrating a side wall portion of a container in the cooling device of the first embodiment at a position where the transport pipe is provided;

FIG. 8B is a cross-sectional view illustrating the side wall portion of the container in the cooling device of the first embodiment at a position where the transport pipe is not provided;

FIG. 9 is a side view illustrating the one end portion of the transport pipe in the cooling device of the first embodiment together with a part of the evaporation unit;

FIG. 10 is a graph indicating a relationship between an inner diameter of the transport pipe and a height of a water column rising in the transport pipe;

FIG. 11 is a cross-sectional view illustrating a state where a refrigerant evaporates in the cooling device of the first embodiment;

FIG. 12 is a cross-sectional view illustrating a state where the refrigerant condenses in the cooling device of the first embodiment;

FIG. 13 is a cross-sectional view taken along a line 13-13 of FIG. 4, illustrating the cooling device of the first embodiment;

FIG. 14 is a plan view illustrating the internal structure of the cooling device of the present disclosure together with an injection hole and an injection pipe;

FIG. 15 is a cross-sectional view taken along a line 15-15 of FIG. 14, illustrating the internal structure of the cooling device of the present disclosure;

FIG. 16 is a cross-sectional view illustrating the injection pipe of the cooling device of the present disclosure in an unsealed state;

FIG. 17 is a cross-sectional view illustrating the injection pipe of the cooling device of the present disclosure in a compressed and sealed state;

FIG. 18 is a cross-sectional view illustrating the injection hole of the cooling device of the present disclosure in a state of being sealed with a plug at a tip of the injection pipe;

FIG. 19 is a plan view illustrating an internal structure of a cooling device of a second embodiment;

FIG. 20 is a plan view illustrating an internal structure of a cooling device of a third embodiment;

FIG. 21 is a cross-sectional view illustrating a structure of the side wall portion of the container in the technology of the present disclosure, which is different from that of FIG. 8A, at a position where the transport pipe is provided;

FIG. 22 is an enlarged perspective view illustrating a net member and the vicinity thereof in a first modification of the cooling device of the technology of the present disclosure;

FIG. 23 is a plan cross-sectional view partially illustrating a second modification of the cooling device of the technology of the present disclosure; and

FIG. 24 is a cross-sectional view taken along a line 24-24 of FIG. 23, partially illustrating the second modification of the cooling device of the technology of the present disclosure.

### DESCRIPTION OF EMBODIMENTS

In order to cool a plurality of heat generation members as objects to be cooled, for example, it is conceivable to provide an independent cooling device for each of the objects to be cooled.

In this case, in order to properly cool each of the objects to be cooled, a cooling capacity of each cooling device is set according to the corresponding object to be cooled. However, when each of the cooling devices is set to have a sufficient cooling capacity for the corresponding object to be cooled, the size of the cooling device may increase and mounting density of various parts including the object to be cooled may decrease. For example, there is room for improvement in order to properly cool the plurality of objects to be cooled.

As one aspect, the disclosed technology of the present application aims to properly cool a plurality of objects to be cooled in a cooling device that transfers heat by a phase change between a gas phase and a liquid phase of a refrigerant in a container.

A cooling device 42 of a first embodiment will be described in detail with reference to the drawings.

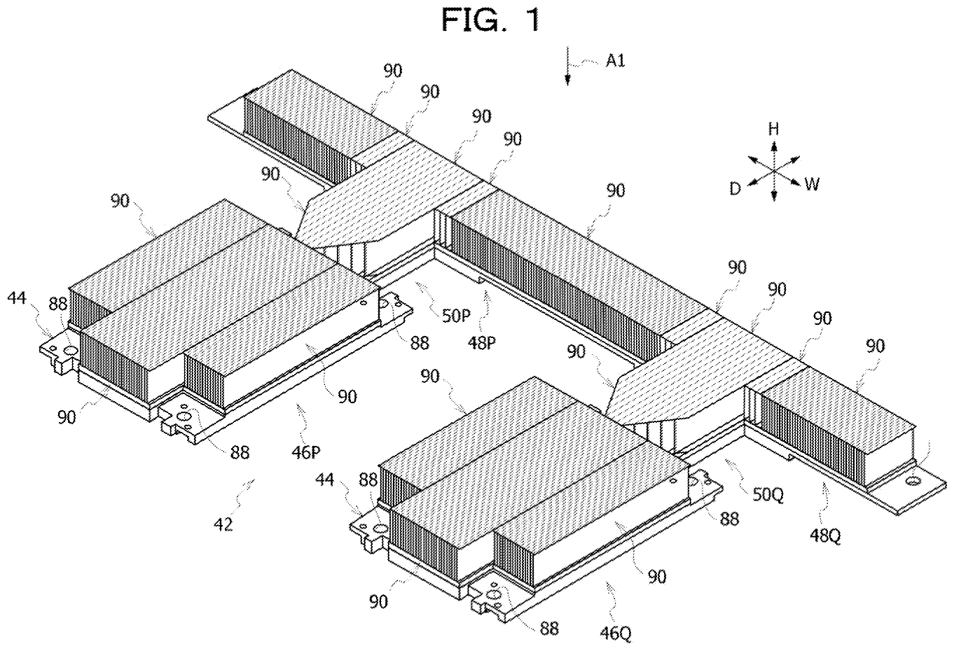

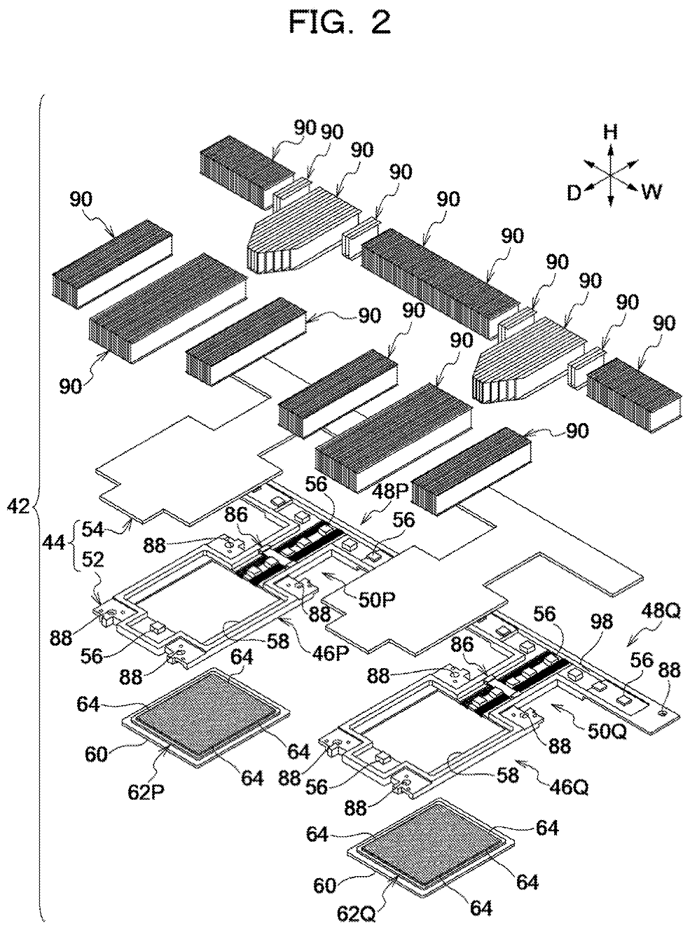

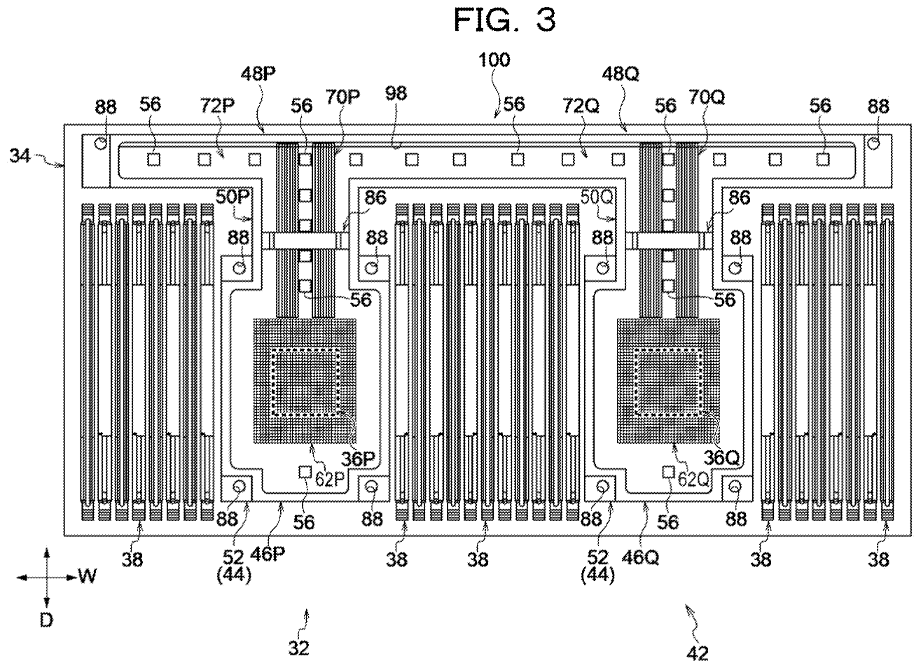

FIGS. 1 and 2 illustrate the cooling device 42 of the first embodiment. Furthermore, FIG. 3 illustrates an electronic device 32 including the cooling device 42. Examples of the electronic device 32 include, but are not limited to, an information communication device such as a server.

The electronic device 32 includes a substrate 34 having rigidity and an insulation property. A plurality of elements 36P, 36Q, and 38 is mounted on the substrate 34. The types of the elements 36P, 36Q, and 38 are not particularly limited, but in the example illustrated in FIG. 3, the elements 36P and 36Q are processor chips and the element 38 is a memory module. In this case, the elements 36P and 36Q are examples of heating elements. In addition, in order to cool the elements 36P and 36Q, the cooling device 42 is arranged in contact with the elements 36P and 36Q.

Hereinafter, in a case where the element 36P and the element 36Q are not particularly distinguished, they will be described as the elements 36. Similarly, in various members, in a case where members having “P” or “Q” attached to reference signs are not particularly distinguished, only numerals are given as reference signs without attaching “P” and “Q”.

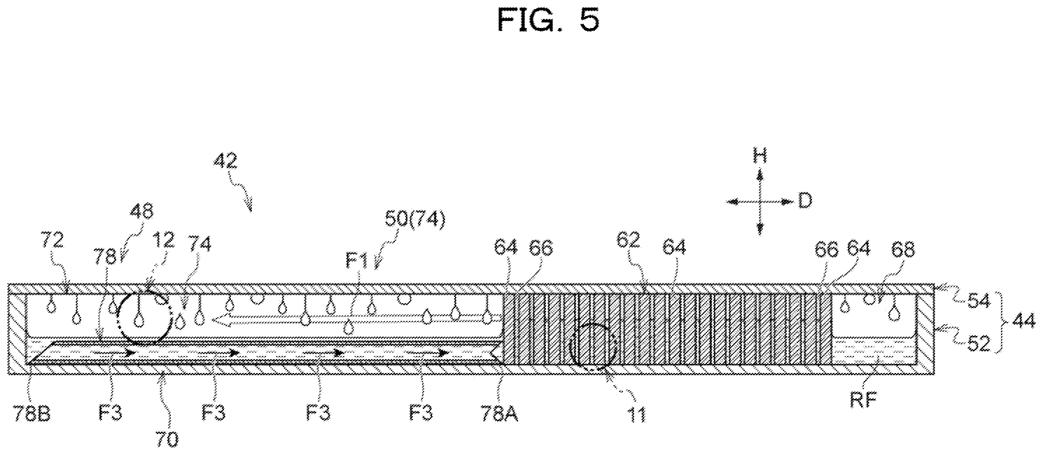

As illustrated in FIGS. 1 to 5, the cooling device 42 includes a container 44. In the container 44, a refrigerant RF (see FIG. 5) is sealed. In addition, the cooling device 42 includes heat reception units 46P and 46Q, heat radiation units 48P and 48Q, and connection units 50P and 50Q, respectively corresponding to the elements 36P and 36Q.

The type of the refrigerant RF is not limited as long as heat may be transferred by circulating the refrigerant RF while performing a phase transition between a liquid phase and a gas phase in the container 44, and for example, water may be used. Although oil or alcohol may be used instead of water, water is easily available and easy to handle, and water is used also in the present embodiment.

The heat reception units 46P and 46Q are portions that are arranged in contact with the corresponding elements 36P and 36Q as illustrated in FIG. 3, and receive heat of the elements 36P and 36Q. The heat reception units 46P and 46Q includes evaporation units 62P and 62Q, respectively, which vaporize the refrigerant RF in the liquid phase by the heat.

The heat radiation units 48P and 48Q are portions that are arranged separately from the corresponding heat reception units 46P and 46Q and release heat of the refrigerant RF sealed in the container 44 to the outside. The heat radiation units 48P and 48Q include condensation units 72P and 72Q that liquefy the refrigerant RF in the gas phase by heat radiation.

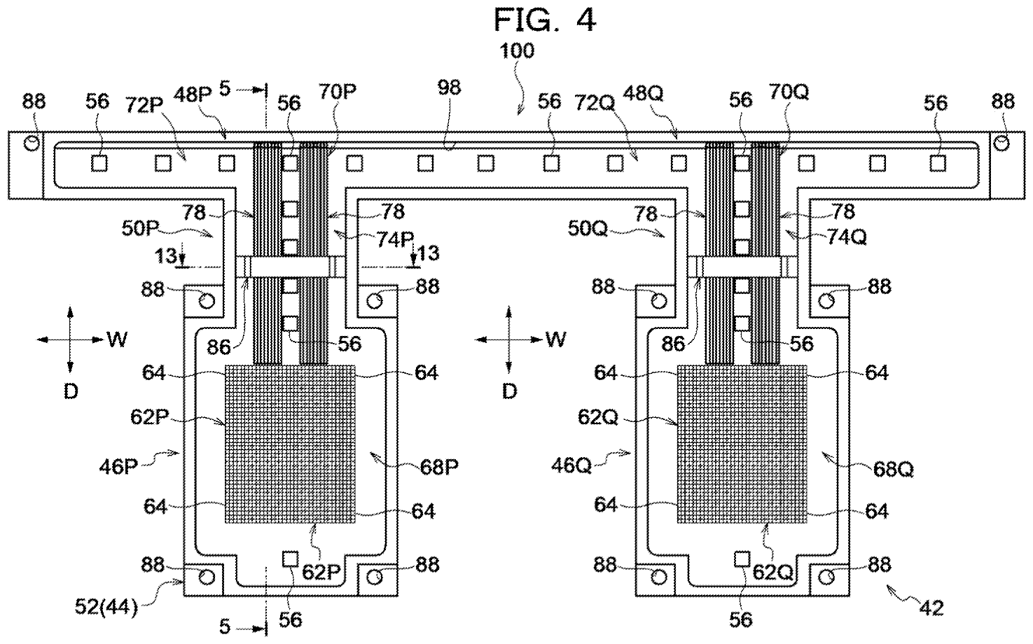

The connection unit 50P is a portion connecting the heat reception unit 46P and the heat radiation unit 48P, and is also a movement region 74P (see FIG. 4) in which the refrigerant RF moves between the evaporation unit 62P and the condensation unit 72P. The connection unit 50Q is a portion connecting the heat reception unit 46Q and the heat radiation unit 48Q, and is also a movement region 74Q (see FIG. 4) in which the refrigerant RF moves between the evaporation unit 62Q and the condensation unit 72Q.

Note that a part of heat of the refrigerant RF in the gas phase state is discharged to the outside also at the connection units 50P and 50Q, and the refrigerant RF is liquefied.

In the drawings, a width direction, a depth direction, and a height direction of the container 44 are indicated by an arrow W, an arrow D, and an arrow H, respectively. In the present embodiment, the heat radiation unit 48P has a shape wider in the width direction and shorter in the depth direction than the heat reception unit 46P. The connection unit 50P is narrower in the width direction than the heat reception unit 46P, and has a depth for connecting the heat reception unit 46P and the heat radiation unit 48P.

Similarly, the heat radiation unit 48Q has a shape wider in the width direction and shorter in the depth direction than the heat reception unit 46Q. The connection unit 50Q is narrower in the width direction than the heat reception unit 46Q, and has a depth for connecting the heat reception unit 46Q and the heat radiation unit 48Q.

As illustrated in FIG. 2, the container 44 has a structure in which two plate materials, a bottom plate 52 and a top plate 54, are fixed in a state of being stacked in a thickness direction (height direction).

A plurality of columns 56 is erected from the bottom plate 52. Tips (upper ends) of the columns 56 are in contact with the top plate 54, and the top plate 54 is supported by the columns 56. The inside of the container 44 is maintained in a low pressure state, and even in the low pressure state, the columns 56 maintain an interval between the top plate 54 and the bottom plate 52 and secure an internal volume of the container 44.

In the present embodiment, as illustrated in FIGS. 2 and 4, the plurality of columns 56 is arranged in the heat radiation units 48P and 48Q at intervals in the width direction of the container 44, and is further arranged in the connection units 50P and 50Q at intervals in the depth direction of the container 44. In addition, also in each of the heat reception units 46P and 46Q, one column 56 is provided on an opposite side of the connection unit 50 with the evaporation unit 62 in between.

As illustrated in FIG. 2, in the bottom plate 52, an opening 58 is formed in each of portions of the heat reception units 46P and 46Q. By fitting heat reception plates 60 into the openings 58, a sealed structure in the container 44 is achieved by the bottom plate 52, the top plate 54, and the heat reception plates 60.

On the heat reception plate 60, a plurality of column members 64 is erected toward the top plate 54. As illustrated in detail also in FIGS. 5 to 7, the plurality of column members 64 is arranged at regular intervals in the width direction and the depth direction, and grid-like grooves 66 are formed between the column members 64. A groove width W1 of the groove 66 is narrower than an inner diameter N1 of a transport pipe 78 described later.

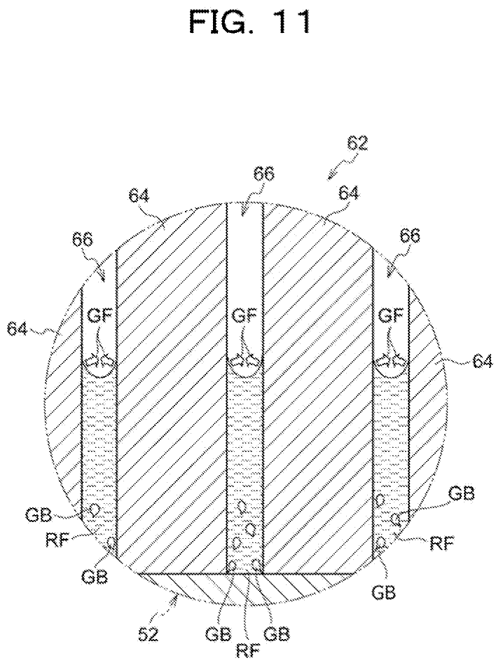

As illustrated in FIG. 11, in the groove 66, vaporization of the refrigerant RF in the liquid phase is promoted by heat from the heat reception units 46P and 46Q. This “vaporization” includes, in addition to “evaporation” indicating vaporization from a surface of the refrigerant RF as indicated by arrows GF, “boiling” indicating vaporization from the inside of the refrigerant RF as indicated by bubbles GB. Hereinafter, “evaporation” will be used to refer to both of these. Portions including the column members 64 are portions where the refrigerant RF in the liquid phase evaporates in this way, and are the evaporation units 62P and 62Q.

Tips of the column members 64 are in contact with the top plate 54. Also with this configuration, under the low pressure state inside the container 44, the interval between the top plate 54 and the bottom plate 52 is maintained, and the internal volume of the container 44 is secured.

As illustrated in FIG. 4, around the column members 64, diffusion regions 68P and 68Q are formed between the top plate 54 and the bottom plate 52. The refrigerant RF in the gas phase evaporated in the evaporation units 62P and 62Q diffuses into the corresponding diffusion regions 68P and 68Q, respectively. A part of the refrigerant RF in the gas phase diffused in the diffusion regions 68P and 68Q is condensed and liquefied by heat radiation from the top plate 54 to the air through fins 90 described later in the evaporation units 62P and 62Q, and becomes the refrigerant RF in the liquid phase.

Moreover, between the top plate 54 and the bottom plate 52, the movement region 74P is formed between the heat reception unit 46P and the heat radiation unit 48P, and the movement region 74Q is formed between the heat reception unit 46Q and the heat radiation unit 48Q. The refrigerant RF in the gas phase evaporated in the evaporation units 62P and 62Q moves to the heat radiation units 48P and 48Q through the corresponding movement regions 74P and 74Q. During this movement, heat of the refrigerant RF is discharged to the outside of the container 44, so that the refrigerant RF in the gas phase is condensed and liquefied. For example, the connection units 50P and 50Q and the heat radiation units 48P and 48Q are also portions where the refrigerant RF in the gas phase is condensed in this way.

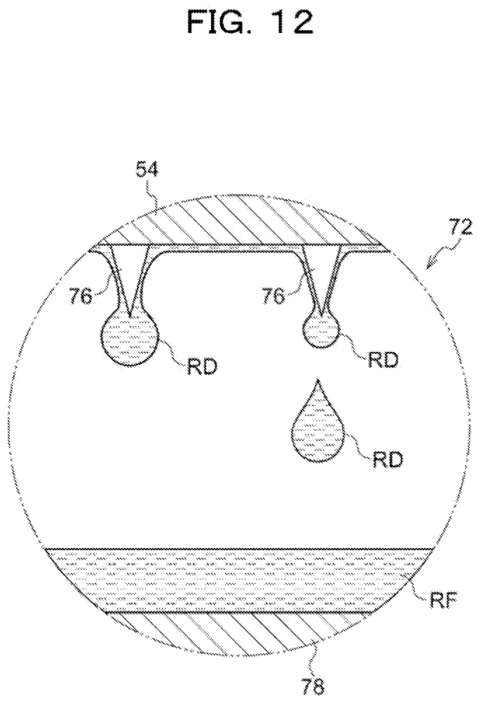

As illustrated in FIG. 12, a plurality of protrusions 76 is formed on the top plate 54 toward a bottom portion of the bottom plate 52 (see FIG. 5). Each of the protrusions 76 has a shape that tapers toward a tip side. By providing such protrusions 76, as compared with a structure without the protrusions 76, a surface area of a top surface in the condensation unit 72 is larger.

As illustrated in FIGS. 4 to 6, inside the container 44, a transport unit 70P is arranged between the evaporation unit 62P and the condensation unit 72P, and a transport unit 70Q is arranged between the evaporation unit 62Q and the condensation unit 72Q. For example, the evaporation unit 62P and the transport unit 70P are arranged in one set corresponding to the condensation unit 72P, and the evaporation unit 62Q and the transport unit 70Q are arranged in one set corresponding to the condensation unit 72Q.

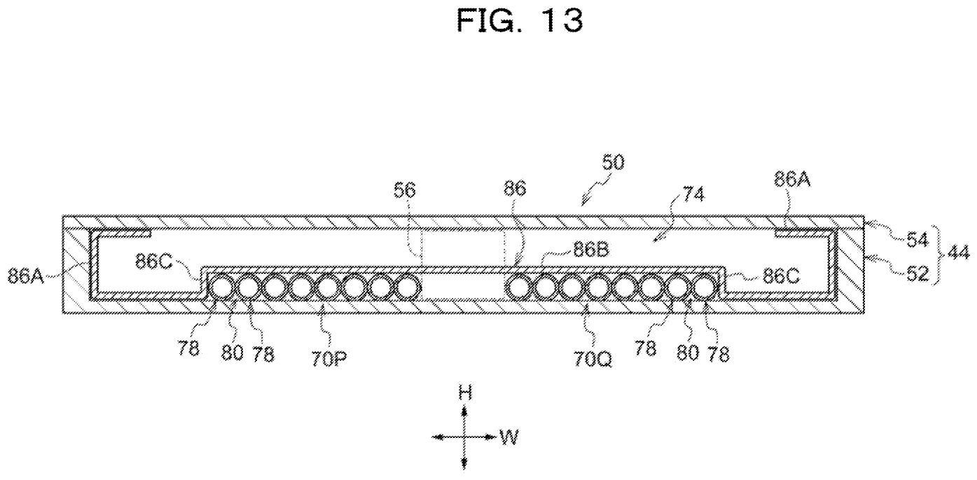

Both the transport units 70P and 70Q have the transport pipes 78 extending in the depth direction. In each of the transport units 70P and 70Q, one transport pipe 78 may be arranged, but in the present embodiment, a plurality of transport pipes 78 is arranged in both the transport units 70P and 70Q. For example, in an example illustrated in FIG. 13, in each of the transport units 70P and 70Q, a set of eight transport pipes 78 arranged adjacent to each other in the width direction is arranged in two sets with the column 56 in between, and a total of 16 transport pipes 78 are arranged. A longitudinal direction of the transport pipe 78 coincides with the depth direction of the container 44 (arrow D direction).

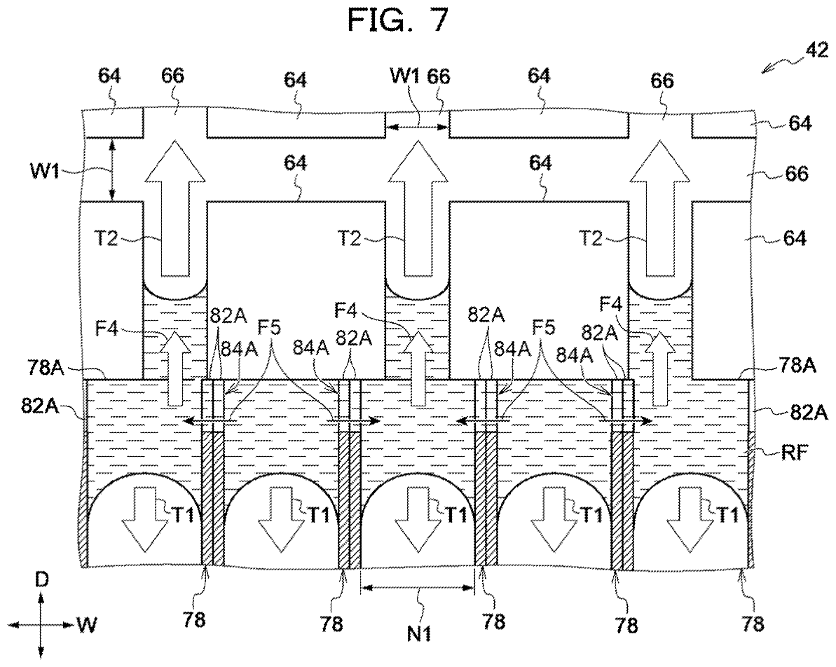

As illustrated in FIG. 7, the inner diameter N1 of the transport pipe 78 is set such that the refrigerant RF in the liquid phase may be transported by a capillary phenomenon and a sufficient amount of the refrigerant RF may be transported to the evaporation units 62P and 62Q by the whole of the plurality of transport pipes 78.

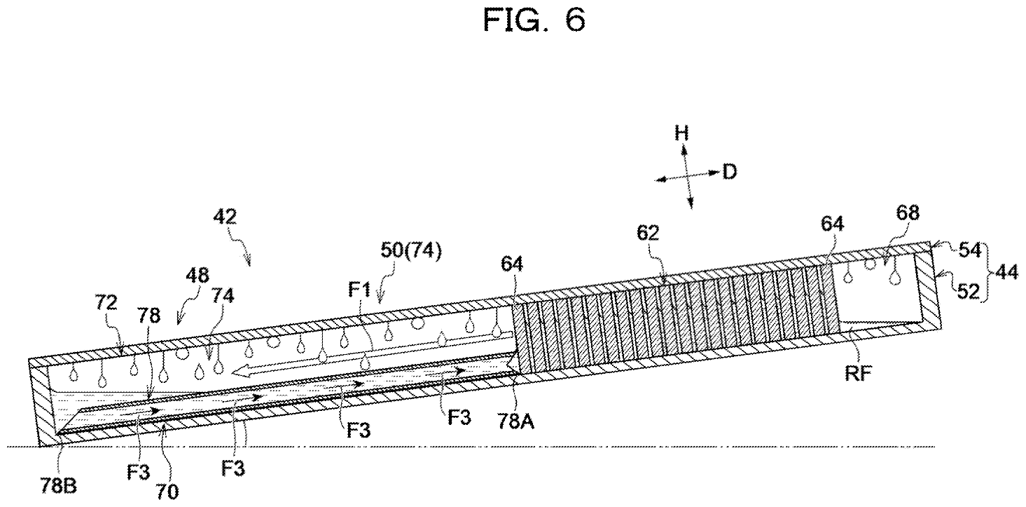

Moreover, an upper limit of the inner diameter N1 of the transport pipe 78 is determined so that the refrigerant RF may be transported from another end portion 78B to one end portion 78A by the capillary phenomenon even in a case where the cooling device 42 is inclined such that the one end portion 78A is higher than the another end portion 78B (see FIG. 6).

Note that, in the present embodiment, as illustrated in FIG. 13, spaces 80 between the transport pipes 78 arranged adjacent to each other in the width direction and the bottom plate 52 are also regions capable of transporting the refrigerant RF in the liquid phase by the capillary phenomenon.

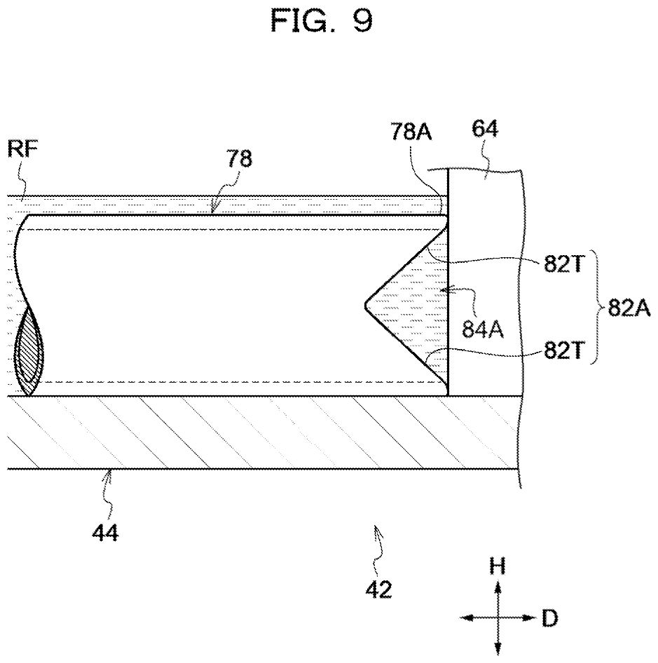

The one end portions 78A of the transport pipes 78 face the column members 64, as also illustrated in FIGS. 7 and 9. In the first embodiment, a gap portion is provided at the one end portion 78A. For example, by cutting out the transport pipe 78 at the one end portion, an inclined portion 82A is formed so as to be inclined relative to the longitudinal direction of the transport pipe 78. The inclined portion 82A is an example of the gap portion in the first embodiment.

For example, in the present embodiment, as illustrated in FIG. 9, the inclined portion 82A has a V-shape having a pair of inclined surfaces 82T formed so as to approach each other as they are separated from the column members 64.

A portion where the inclined portion 82A is provided, which is a region between the inclined surfaces 82T, is a gap 84A in which the refrigerant RF in the liquid phase moves from the transport pipe 78 to the evaporation units 62P and 62Q.

A plurality of the inclined portions 82A is formed in one transport pipe 78 at regular intervals in a circumferential direction. In the present embodiment, as illustrated in FIG. 7, two inclined portions 82A are formed in one transport pipe 78 so as to be separated from each other in the width direction of the container 44 (arrow W direction).

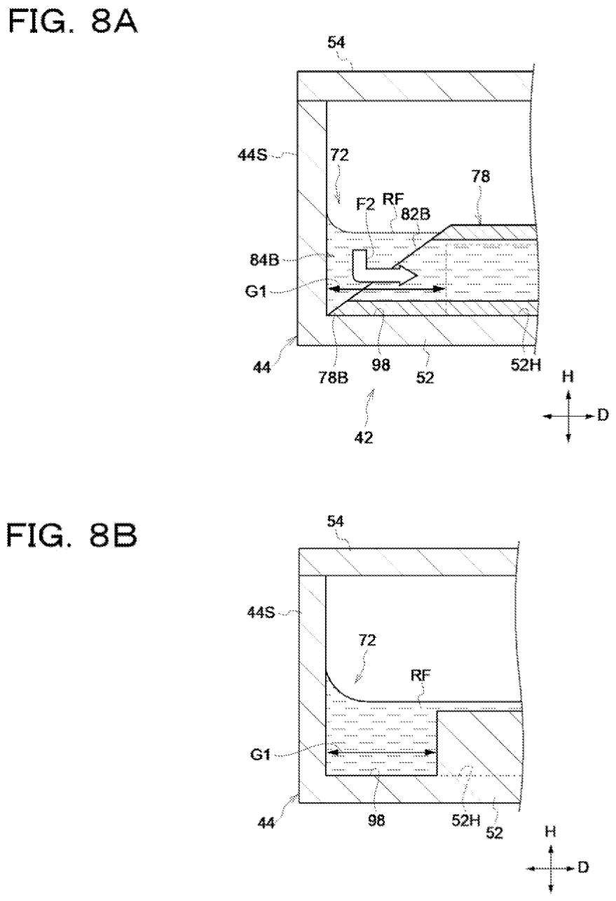

The another end portion 78B of the transport pipe 78 faces a side wall 44S of the container 44, as illustrated in FIG. 8A. The side wall 44S is a side wall forming an end on a front side in the depth direction (condensation unit 72 side).

The bottom plate 52 of the container 44 is formed with a recess 52H for accommodating the transport pipe 78. An upper surface of the recess 52H and an upper surface of a movement groove 98 described later have the same height in the height direction of the container 44 (arrow H direction).

A second gap portion is provided in the another end portion 78B of the transport pipe 78. For example, a second inclined portion 82B is formed by inclining the another end portion 78B in one direction relative to the longitudinal direction of the transport pipe 78, and a region between the side wall 44S and the second inclined portion 82B is a second gap 84B in which the refrigerant RF in the liquid phase moves from the condensation units 72P and 72Q into the transport pipe 78.

As also illustrated in FIG. 13, a fixture 86 is arranged inside the container 44 at each of portions of the connection units 50P and 50Q. The fixture 86 includes fitting portions 86A fitted between the top plate 54 and the bottom plate 52 on both sides in the width direction (arrow W direction), and a pressing portion 86B that presses the plurality of transport pipes 78 toward the bottom plate 52 at the center in the width direction. The transport pipes 78 are pressed and fixed to the bottom plate 52 by the pressing portion 86B. Since the plurality of transport pipes 78 is fixed in contact with the bottom plate 52, a sufficient flow path cross-sectional area is secured between the top plate 54 and the transport pipe 78 for substantially moving the refrigerant RF in the gas phase.

Moreover, since the sets of the transport pipes 78 are positioned between the column 56 and side surface portions 86C of the pressing portion 86B, the sets are also held in the width direction.

As illustrated in FIGS. 3 and 4, in the first embodiment, the condensation units 72P and 72Q communicate with each other. For example, in the width direction (arrow W direction), there is no wall or the like between the condensation unit 72P and the condensation unit 72Q, and the condensation unit 72P and the condensation unit 72Q have a continuous shape with a fixed cross-sectional shape. With this configuration, the refrigerant RF may move between the evaporation unit 62P and the evaporation unit 62Q via the transport unit 70P, the condensation unit 72P, the condensation unit 72Q, and the transport unit 70Q.

In the condensation units 72P and 72Q integrated in this way, the movement groove 98 is formed along the width direction (arrow W direction), as illustrated in FIG. 8B. The movement groove 98 is formed in a groove width G1 capable of moving, by surface tension acting on the refrigerant RF in the liquid phase, the refrigerant RF in any of the width directions. Moreover, this groove width G1 is set wider than the inner diameter N1 of the transport pipe 78. Thus, the surface tension acting on the refrigerant RF in the liquid phase is larger in the transport pipe 78 than in the movement groove 98. In addition, in the first embodiment, a movement portion in the technology of the present disclosure has the structure in which the two condensation units 72P and 72Q are communicated with each other, and a movement portion 100 is formed by providing the movement groove 98 in the communication portion.

In the examples illustrated in FIGS. 3 and 4, the condensation units 72P and 72Q are formed linearly as a whole. In addition, both the set of the evaporation unit 62P and the transport unit 70P and the set of the evaporation unit 62Q and the transport unit 70Q are arranged on one side when viewed from the condensation units 72P and 72Q which are thus formed linearly.

As illustrated in FIGS. 1 to 4, the bottom plate 52 of the container 44 is provided with fastening holes 88. Fasteners such as screws are inserted into the fastening holes 88 and fastened to the substrate 34 to fix the cooling device 42 to the substrate 34. Since the element 36 to be cooled is mounted on the substrate 34, the cooling device 42 is also fixed to the element 36.

Note that the top plate 54 has a shape that avoids the fastening holes 88 when viewed in an overlapping direction with the bottom plate 52 (arrow Al direction illustrated in FIG. 1). Thus, when the cooling device 42 is fixed to the substrate 34, it is possible to perform a fastening operation (for example, a screw turning operation) on the fasteners without being disturbed by the top plate 54.

As illustrated in FIGS. 1 and 2, the fins 90 are attached to the top plate 54. The fins 90 increase a substantial surface area of the container 44, which is a heat radiation area for heat radiation to the outside (air cooling). For example, in the present embodiment, the fins 90 are installed in substantially an entire area of the top plate 54, and a wide heat radiation area is secured.

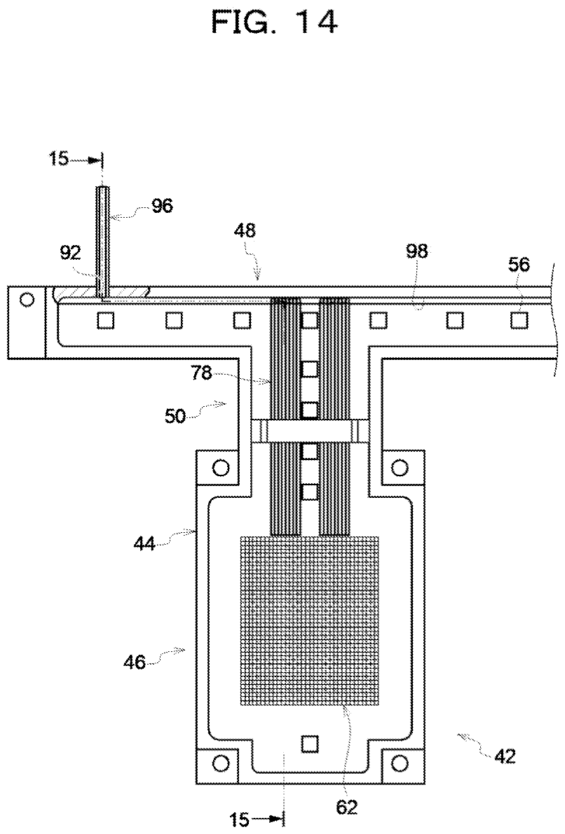

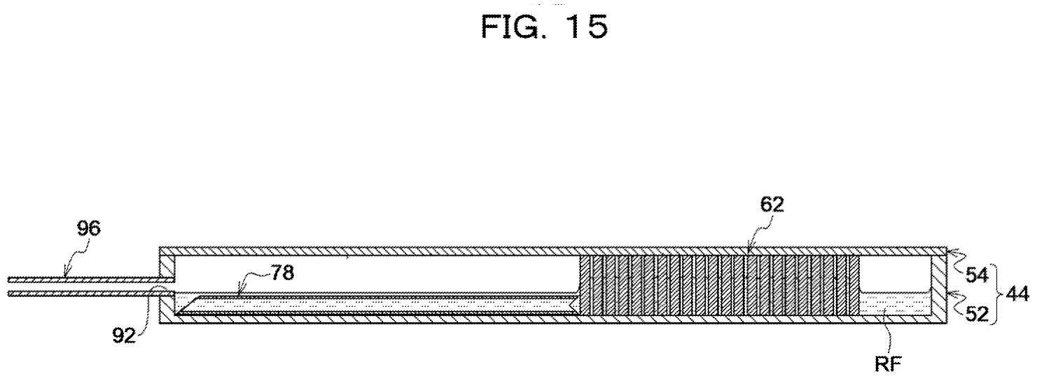

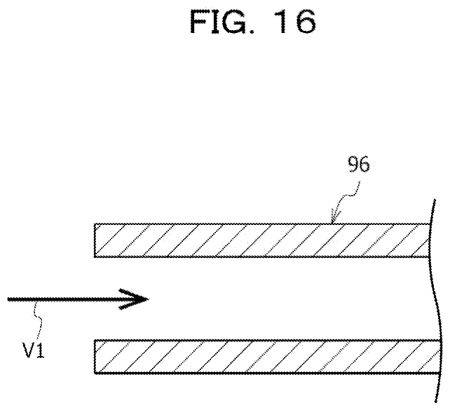

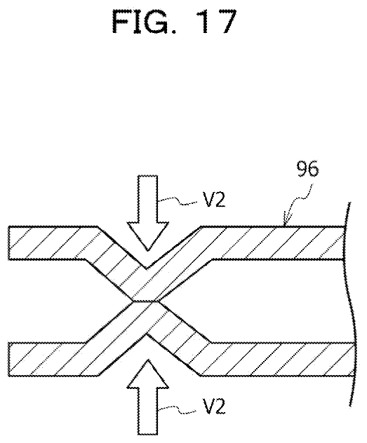

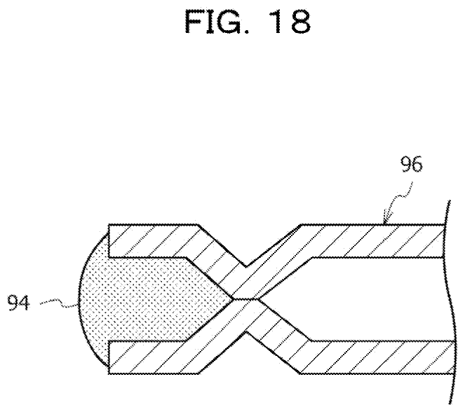

As illustrated in FIGS. 14 and 15, the container 44 is provided with an injection hole 92 that communicates the inside and the outside of the container 44. An injection pipe 96 extends from the injection hole 92 to the outside of the container 44. To inject the refrigerant RF into the container 44, air in the container 44 is discharged by using a vacuum pump or the like. Thereafter, as indicated by an arrow V1 in FIG. 16, the refrigerant is injected through the injection pipe 96. Then, the refrigerant in the container 44 is heated and boiled, and dissolved air in the refrigerant RF is discharged to the outside of the container 44. Note that this operation is not needed in the case of using a degassed refrigerant from which dissolved air has been removed in advance. Next, as indicated by arrows V2 in FIG. 17, the injection pipe 96 is compressed from the outside and sealed. Moreover, as illustrated in FIG. 18, the injection pipe 96 is more tightly sealed by filling a tip of the injection pipe 96 with a plug 94. For example, since the injection hole 92 is provided, the refrigerant RF may be injected into the inside of the container 44 through the injection hole 92. Then, after the injection, the injection hole 92 is sealed with the plug 94, so that the refrigerant RF may be sealed inside the container 44. Note that, in the drawings other than FIGS. 17 to 21, illustration of the injection hole 92, the plug 94, and the injection pipe 96 are omitted.

Next, operations of the present embodiment will be described.

When the heat reception unit 46 receives heat from the element 36, the heat vaporizes the refrigerant RF in the liquid phase in the grooves 66 in the evaporation unit 62, as illustrated in FIG. 5. For example, the refrigerant RF in the liquid phase becomes a gas phase due to evaporation from the surface of the refrigerant RF (see arrows GF) and boiling from the inside of the refrigerant RF (see bubbles GB).

The refrigerant RF in the gas phase is diffused into the diffusion region 68 and moves to the heat radiation unit 48 through the movement region 74 (see an arrow F1 of FIGS. 5 and 6). In the diffusion region 68 and the movement region 74, a part of the refrigerant RF in the gas phase is condensed and liquefied by heat radiation through the fins 90. Moreover, the refrigerant RF that has reached the heat radiation unit 48 while maintaining the gas phase state is also cooled in the heat radiation unit 48 through the fins 90, so that the refrigerant RF is condensed and liquefied. By liquefying the refrigerant RF in the gas phase in this way, heat of condensation is released from the top plate 54 to

Fujitsu Ref. No.: 20-01530 the outside of the container 44. As a result, the heat of the element 36 is discharged into the outside air.

As illustrated in FIG. 4, the condensation unit 72 is formed wider in the width direction (arrow W direction) than the evaporation unit 62. Thus, as compared with a structure in which the condensation unit 72 is not wide in this way, a large area for heat radiation from the refrigerant RF in the gas phase may be secured, and condensation of the refrigerant RF may be promoted.

Inside the container 44, the refrigerant RF in the liquid phase enters the inside of the transport pipe 78 from the another end portion 78B of the transport pipe 78, as indicated by an arrow F2 in FIG. 8A. Moreover, the refrigerant RF is transported to the one end portion 78A, which is, toward the evaporation unit 62 by the capillary phenomenon, as indicated by arrows F3 in FIGS. 5 and 6. Furthermore, also in the spaces 80 between the transport pipes 78 and the bottom plate 52 (see FIG. 13), the refrigerant RF in the liquid phase is transported to the evaporation unit 62 by the capillary phenomenon.

Then, in the evaporation unit 62, the refrigerant RF in the liquid phase is evaporated and vaporized again in the grooves 66. In this way, inside the container 44, the refrigerant RF is circulated in the evaporation unit 62 and the condensation unit 72 while repeating the phase transition between the liquid phase and the gas phase. The heat received by the heat reception unit 46 may be transferred to the heat radiation unit 48, and with this configuration, the element 36 to be cooled may be cooled.

As illustrated in FIG. 7, in the present embodiment, the groove width W1 of the groove 66 of the evaporation unit 62 is smaller than the inner diameter N1 of the transport pipe 78.

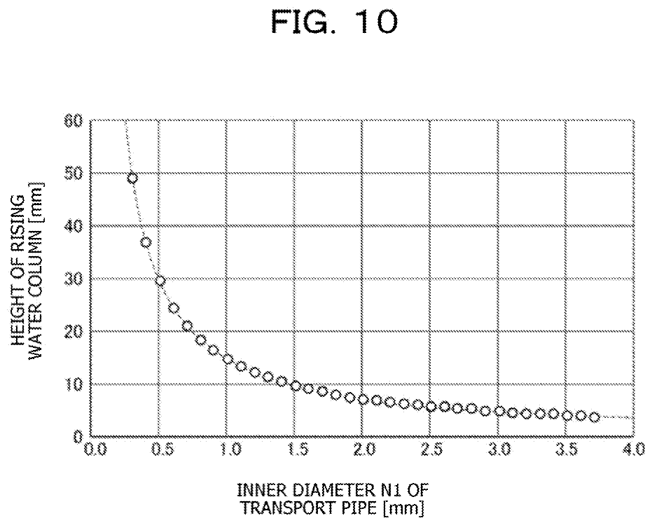

FIG. 10 illustrates a relationship between the inner diameter N1 of the transport pipe 78 and a rising height of a liquid column that rises in the transport pipe 78 due to the surface tension (capillary phenomenon), in a case where a liquid temperature is 25° C. This graph is an example of water used as the refrigerant RF in the present embodiment.

As is known from this graph, the smaller the inner diameter N1 of the transport pipe 78, the higher the rising height of the liquid column. For example, as the inner diameter N1 is smaller, the refrigerant RF may be raised with larger surface tension.

In the transport pipe 78, as indicated by the arrows F3 in FIGS. 5 and 6, the refrigerant RF in the liquid phase is transported to the evaporation unit 62. However, at the one end portion 78A of the transport pipe 78, as illustrated in FIG. 7, a suction force T1 to the refrigerant RF in a direction away from the evaporation unit 62 may act due to the surface tension of the refrigerant RF in the liquid phase inside. On the other hand, in the evaporation unit 62, a suction force T2 to the refrigerant RF that draws the refrigerant RF into the inside of the evaporation unit 62 may act due to the surface tension of the refrigerant RF in the liquid phase in the grooves 66. The suction force T1 and the suction force T2 are forces in opposite directions, but since the suction force T2 is larger, the refrigerant RF flows from the transport pipe 78 toward the evaporation unit 62 as indicated by arrows F4.

Here, for example, as illustrated in FIG. 6, a case is considered where the cooling device 42 is used in an inclined manner such that the one end portion 78A is higher than the another end portion 78B. As an example, it is assumed that the one end portion 78A is about 25 mm higher than the another end portion 78B. In this case, it may be seen that, when the inner diameter N1 of the transport pipe 78 is set to 0.6 mm or less, the refrigerant RF may be transported from the another end portion 78B toward the one end portion 78A in the transport pipe 78 due to the surface tension.

In this way, from the viewpoint of increasing the surface tension acting on the refrigerant RF in the transport pipe 78, it is sufficient that the inner diameter N1 of the transport pipe 78 is made smaller. Note that, when the inner diameter N1 of the transport pipe 78 is made smaller, the flow path cross-sectional area of the refrigerant RF also becomes smaller, so that the amount of the refrigerant RF that may be transported per unit time also becomes smaller. Thus, a lower limit value of the inner diameter N1 of the transport pipe 78 is determined from the viewpoint of securing the transport amount of the refrigerant RF per unit time.

As illustrated in FIG. 7, in the present embodiment, the groove width W1 of the groove 66 is narrower than the inner diameter N1 of the transport pipe 78. From the relationship illustrated in FIG. 10, the surface tension acting on the refrigerant RF in the liquid phase in the evaporation unit 62 is larger than the surface tension acting on the refrigerant RF in the liquid phase in the transport pipe 78. Thus, by a difference between the suction force T2 and the suction force T1, a force to move from the transport pipe 78 to the evaporation unit 62 may be caused to act, and the refrigerant RF may be moved from the transport pipe 78 to the evaporation unit 62.

Here, a structure in which the one end portion 78A of the transport pipe 78 is formed flat without providing the gap portion is considered. In the transport pipe having the flat one end portion 78A, when an opening portion of the transport pipe faces the column member 64 and an entire circumference of the opening portion is in contact with the column member 64, the opening portion may be covered by the column member 64. By increasing the inner diameter N1 of the transport pipe, it is possible to secure a range that is not covered by the column member 64 at the opening portion of the transport pipe.

However, as described above, in order to ensure that the surface tension acts on the refrigerant RF, the inner diameter N1 has an upper limit.

On the other hand, in the present embodiment, the inclined portion 82A is provided at the one end portion 78A of the transport pipe 78 as an example of the gap portion. In addition, even when a tip portion of the one end portion 78A is in contact with the evaporation unit 62, the gap 84A is formed between the transport pipe 78 and the evaporation unit 62 so that the one end portion 78A does not contact the evaporation unit 62. For example, the structure is such that the opening portion at the one end portion 78A of the transport pipe 78 is not completely blocked by the column member 64. Thus, as indicated by arrows F5 in FIG. 7, the refrigerant RF in the liquid phase transported by the transport pipe 78 flows into the groove 66 of the evaporation unit 62 through the gap 84A. For example, a structure is achieved that facilitates movement of the refrigerant RF in the liquid phase from the transport pipe 78 to the evaporation unit 62.

In the structure in which the groove width W1 of the groove 66 is narrower than the inner diameter N1 of the transport pipe 78 as described above, the column member 64 becomes relatively thick and covers a wide range of the opening portion of the transport pipe 78. However, even in such a structure, in the present embodiment, since the gap 84A is formed between the transport pipe 78 and the evaporation unit 62, the refrigerant RF in the liquid phase may be reliably moved from the transport pipe 78 to the evaporation unit 62.

In the first embodiment, the gap portion is the inclined portion 82A provided at the one end portion 78A of the transport pipe 78. When the gap portion is provided in the transport pipe 78 in this way, no other member for forming the gap 84A is needed, and the structure of the cooling device 42 may be simplified.

The gap portion is the inclined portion 82A in the example described above. For example, the gap 84A may be formed by the simple structure in which the one end portion 78A of the transport pipe 78 is inclined relative to the longitudinal direction of the transport pipe 78.

As illustrated in FIG. 9, the inclined portion 82A has the pair of inclined surfaces 82T. The inclined surfaces 82T are surfaces that approach each other as they are separated from the evaporation unit 62. By forming the inclined portion 82A including such inclined surfaces 82T, a structure may be achieved in which the gap 84A is formed without making the depth to cut the inclined portion 82A (the length of the portion cut from the evaporation unit 62 side) excessively long.

Note that the one end portion 78A of the transport pipe 78 may be provided with an inclined portion inclined in one direction in a similar manner to the second inclined portion 82B of the another end portion 78B.

Furthermore, the inclined portion 82A as an example of the gap portion is provided at a plurality of places (two places in the present embodiment) in the circumferential direction in one transport pipe 78. Since a plurality of the gaps 84A is formed by providing the plurality of gap portions, it is possible to secure a cross-sectional area of a portion where the refrigerant RF flows from the transport pipe 78 to the evaporation unit 62 wider, compared with that of a structure in which only one gap portion is provided in one transport pipe 78.

As illustrated in FIG. 8A, the another end portion 78B of the transport pipe 78 is provided with the second inclined portion 82B as an example of the second gap portion, and the second gap 84B is formed between the another end portion 78B and the side wall 44S of the container 44. For example, the structure is such that the opening portion at the another end portion 78B of the transport pipe 78 is not blocked by the side wall 44S. Thus, a structure is achieved in which the refrigerant RF in the liquid phase in the container 44 easily flows into the inside of the transport pipe 78 through the second gap 84B.

In the first embodiment, the transport unit 70 includes the plurality of transport pipes 78. As the transport unit 70, for example, a plate-shaped member or the like having a hole formed as a flow path for the refrigerant RF in the liquid phase may be used instead of or in combination with the transport pipes 78. Since the transport unit 70 has the transport pipes 78, the transport unit 70 may be formed with a simple structure.

In addition, the plurality of transport pipes 78 is arranged in parallel. As described above, in terms of increasing the surface tension acting on the refrigerant RF in the liquid phase flowing through the transport pipe 78, since the inner diameter N1 of the transport pipe 78 has an upper limit, it is difficult to secure a sufficient flow rate with only one transport pipe 78. On the other hand, by arranging the plurality of transport pipes 78 in parallel, the transport pipes 78 may secure a larger flow rate as a whole.

Since the transport pipes 78 are fixed to the container 44 by the fixture 86, displacement or falling of the transport pipes 78 may be suppressed.

The plurality of transport pipes 78 is arranged so that a flow path for the refrigerant RF in the liquid phase is formed also between the two adjacent transport pipes 78 and the bottom plate 52. Since not only the inside of the transport pipe 78 but also the outside of the transport pipe 78 is used as a region where the refrigerant RF in the liquid phase flows, a larger flow rate of the refrigerant RF may be secured as compared with a structure in which such a flow path is not formed.

The cooling device 42 of the first embodiment is a device capable of cooling a plurality of elements, the two elements 36P and 36Q in the example illustrated in FIG. 3.

Incidentally, in a case where the two elements 36P and 36Q generate heat, there is often a case where there is a difference in an amount of heat generation as compared with a case where the amounts of heat generation of both the elements 36P and 36Q reach an upper limit at the same time. For example, when the amount of heat generation of the element 36P is larger than that of the element 36Q, more refrigerant RF evaporates in the evaporation unit 62P on which the heat of the element 36P acts than in the evaporation unit 62Q on which the heat of the element 36Q acts. In contrast, when the amount of heat generation of the element 36Q is larger than that of the element 36P, more refrigerant RF evaporates in the evaporation unit 62Q than in the evaporation unit 62P.

Here, a cooling device having a structure in which the condensation units 72P and 72Q do not communicate with each other and the refrigerant RF is not capable of moving between the condensation units 72P and 72Q as in the present embodiment will be considered as a comparative example.

In the cooling device of the comparative example, on the element 36P side, a structure capable of reliably cooling the element 36P is adopted in a case where the amount of heat generation of the element 36P becomes maximum, and on the element 36Q side as well, a structure capable of reliably cooling the element 36Q is adopted in a case where the amount of heat generation of the element 36Q becomes maximum. For example, as each of the fins 90, a fin that is made larger in size in advance is used so that the element 36P may be cooled when the amount of heat generation of the element 36P reaches the maximum amount. Furthermore, for example, in a structure in which cooling air is applied from the fan to the fins 90, an air blowing capacity of the fan is increased in advance.

The structure in which the fin 90 is made larger in size or the air blowing capacity of the fan is increased in this way may lead to an increase in size of the cooling device itself, and it becomes difficult to mount various parts, elements, and the like at high density as an electronic device.

On the other hand, in the cooling device 42 of the first embodiment, since the condensation units 72P and 72Q communicate with each other, the refrigerant RF in the liquid phase moves between the condensation units 72P and 72Q. With this configuration, more refrigerant RF is supplied to the evaporation unit 62 corresponding to one of the elements 36P and 36Q having a relatively larger amount of heat generation, and it is possible to efficiently perform cooling.

For example, it is assumed that the amount of heat generation of the element 36P becomes relatively larger than the amount of heat generation of the element 36Q. In this case, evaporation of the refrigerant RF is promoted in the evaporation unit 62P than in the evaporation unit 62Q. Thus, a transport amount of the refrigerant RF in the liquid phase from the condensation unit 72P to the evaporation unit 62P becomes larger than a transport amount of the refrigerant RF in the liquid phase from the condensation unit 72Q to the evaporation unit 62Q. The phase transition of the refrigerant RF between the evaporation unit 62P and the condensation unit 72P progresses more than the phase transition of the refrigerant RF between the evaporation unit 62Q and the condensation unit 72Q, and the refrigerant RF in the liquid phase moves from the condensation unit 72Q to the condensation unit 72P. For example, more refrigerant RF is supplied to the evaporation unit 62P in which an amount of evaporation of the refrigerant RF is relatively large.

In the first embodiment, in this way, it is possible to appropriately share and distribute the refrigerant RF in the liquid phase between the condensation units 72P and 72Q so that the element 36P that generates a large amount of heat may be cooled more effectively according to the difference in the amount of heat generation of the elements 36P and 36Q.

Moreover, in order to appropriately distribute the refrigerant RF in the liquid phase between the condensation units 72P and 72Q, for example, devices such as a sensor for detecting the amount of the refrigerant RF and a pump for transporting the refrigerant RF are not needed. The refrigerant RF in the liquid phase may be appropriately distributed between the condensation units 72P and 72Q at low cost and easily without providing and controlling these devices.

In addition, the element 36 may be cooled according to the maximum amount of heat generation of each of the plurality of elements 36 without increasing the sizes of the evaporation unit 62, the condensation unit 72, and the fin 90. By suppressing the increase in the sizes of the evaporation unit 62, the condensation unit 72, and the fin 90, it is possible to contribute to improvement of the mounting density of various parts including the elements 36 and 38 on the substrate 34.

In addition, in the electronic device 32 including the plurality of elements 36, a temperature difference between the plurality of elements 36 may be reduced. By reducing an influence of the temperature difference on transmission and reception of signals between the plurality of elements 36, it is also possible to contribute to improvement of performance of the electronic device 32.

Furthermore, in the cooling device of the comparative example, in order to increase a cooling capacity for one of the plurality of elements 36, an amount of air blown from the fan that blows air to the fin 90 on the side of the element 36 having a high temperature may be increased. However, power consumption increases as the amount of air blown increases. Moreover, when the amount of air blown from a part of the plurality of fans is increased, a balance of an air volume and wind direction in the entire cooling device may be lost, making it not possible to efficiently blow air. Thus, the amount of air blown from all the fans needs to be increased. Increasing the amount of air blown from all the fans in this way causes a further increase in power consumption of the cooling device as a whole.

On the other hand, in the cooling device 42 of the first embodiment, even when there is a difference in the amount of heat generation of the elements 36P and 36Q, the refrigerant RF in the liquid phase moves between the condensation units 72P and 72Q. Thus, when the air volume received by the entire fins 90 is secured, a desired cooling capacity is obtained. In addition, by arranging the fins 90 of the heat radiation units 48P and 48Q at positions where cooling air from the fan is received with high efficiency, it is possible to more highly exhibit the cooling capacity of the cooling device 42 while making the heat radiation units 48P and 48Q smaller in size. Moreover, by making the heat radiation units 48P and 48Q smaller in size, the cooling device 42 may also be made smaller in size, and the mounting density of various parts including the elements 36 and 38 may be improved.

In addition, in the cooling device 42 of the first embodiment, the heat radiation units 48 are commonly used for the plurality of heat reception units 46. Thus, when a total amount of heat cooled by the plurality of heat reception units 46 is within a range of an amount of heat that may be radiated by the plurality of heat radiation units 48 as a whole, the plurality of elements 36 may be reliably cooled. Even when the total amount of heat cooled by the plurality of heat reception units 46 exceeds the amount of heat that may be radiated by the plurality of heat radiation units 48, since the plurality of heat radiation units 48 is commonly used, the cooling capacity of the cooling device 42 as a whole may be efficiently increased by increasing the amount of air blown from the fan, for example.

In the cooling device 42 of the first embodiment, the two condensation units 72P and 72Q are communicated with each other, and the movement groove 98 continuous with these condensation units 72P and 72Q is formed. The groove width G1 of the movement groove 98 (see FIG. 8B) is set so that the refrigerant RF in the liquid phase may be moved in the width direction by the surface tension. Thus, the refrigerant RF in the liquid phase may be efficiently moved between the two condensation units 72P and 72Q as compared with a structure in which the movement groove 98 is not formed.

Moreover, the groove width G1 of the movement groove 98 is larger than the inner diameter N1 of the transport pipe 78. From the relationship illustrated in FIG. 10, the surface tension acting on the refrigerant RF in the liquid phase in the transport pipe 78 is larger than the surface tension acting on the refrigerant RF in the liquid phase in the movement groove 98. Thus, the surface tension suppresses the flow of the refrigerant RF from the transport pipe 78 to the movement groove 98, and the flow of the refrigerant RF from the movement groove 98 toward the transport pipe 78 is reliably generated.

In each of the embodiments described above, the evaporation units 62P and 62Q and the transport units 70P and 70Q are arranged on the same side as the linear condensation units 72P and 72Q. In the electronic device in which the element 36P and the element 36Q are mounted at positions close to each other, this is the arrangement in which the positions of the heat reception unit 46P and the heat reception unit 46Q are corresponded to the elements 36P and 36Q, respectively, so that the heat may be reliably received.

On the other hand, the set of the evaporation unit 62P and the transport unit 70P and the set of the evaporation unit 62Q and the transport unit 70Q may be arranged on an opposite side of the linear condensation units 72P and 72Q. For example, in a case where the elements 36P and 36Q are mounted at distant positions due to a mounting space on the substrate 34, the set of the evaporation unit 62P and the transport unit 70P and the set of the evaporation unit 62Q and the transport unit 70Q may be arranged on the opposite side of the linear condensation units 72P and 72Q.

Moreover, a structure may be adopted in which three or more sets of the evaporation unit 62 and the transport unit 70 are provided so as to correspond to an electronic device including three or more elements 36. In this case, all the sets of the evaporation unit 62 and the transport unit 70 may be on the same side as the plurality of linear condensation units 72, or some sets may be on the opposite side of the plurality of linear condensation units 72.

Moreover, the plurality of condensation units 72 may not be formed linearly as a whole. For example, a structure may be adopted in which the two condensation units 72P and 72Q are integrated by being bent or curved at a boundary portion. When the plurality of condensation units 72 is formed linearly, there is no place where flow path resistance when the refrigerant RF moves between the condensation units 72 becomes large, which is advantageous for smooth movement of the refrigerant RF.

In each of the embodiments described above, the columns 56 are arranged between the top plate 54 and the bottom plate 52 inside the container 44. Since the interval between the top plate 54 and the bottom plate 52 may be maintained by the columns 56, it is possible to secure a volume inside the container 44 for circulating the refrigerant RF while making the phase transition between the liquid phase and the gas phase. For example, the inside of the container 44 is maintained at a low pressure compared to an atmospheric pressure in order to promote vaporization of the refrigerant RF in the liquid phase. In this case, a force in an approaching direction acts on the top plate 54 and the bottom plate 52 due to the pressure difference between a pressure inside the container 44 (vapor pressure of the refrigerant RF in the gas phase) and the atmospheric pressure. Even when such a force acts, the interval between the top plate 54 and the bottom plate 52 may be maintained.

Note that the columns 56 may be provided on the top plate 54 and have a structure in which lower ends contact the bottom plate 52, or may be separate from both the top plate 54 and the bottom plate 52 and have a structure in which upper ends contact the top plate 54 and the lower ends contact the bottom plate 52.

The transport pipes 78 are fixed to the container 44 by the fixture 86. The transport pipes 78 are not fixed to the container by so-called brazing or adhesion, and no solder or adhesive is needed. Since no solder or adhesive is used, the solder or adhesive does not melt due to a temperature change (high temperature) or the like during manufacturing of the cooling device 42.

Furthermore, since the plurality of transport pipes 78 is fixed in contact with the bottom plate 52 by the fixture 86, a sufficient flow path cross-sectional area may be secured between the top plate 54 and the transport pipe 78 for substantially moving the refrigerant RF in the gas phase.

The top plate 54 is provided with the protrusions 76. The refrigerant RF in the gas phase that flows while contacting the top plate 54 is condensed and liquefied by heat radiation to the outside of the container 44 through the top plate 54. At this time, as illustrated in FIG. 12, the protrusions 76 increase a substantial contact area in which the refrigerant RF contacts the top plate 54 as compared with a structure without the protrusions 76. With this configuration, the refrigerant RF in the gas phase is easily liquefied as droplets RD, and liquefaction of the refrigerant RF may be promoted. In addition, since the liquefied refrigerant RF is efficiently dropped along the protrusions 76, a liquid film may be maintained thin at a portion of the top plate 54 where the protrusions 76 are not formed. By maintaining the liquid film thin, a structure may be achieved in which heat transfer from the refrigerant RF in the gas phase to the top plate 54 is efficiently performed, and a high condensation and liquefaction capacity of the refrigerant RF is maintained.

The container 44 is provided with the fastening holes 88. By inserting the fasteners into the fastening holes 88, it is possible to easily achieve a structure in which the cooling device 42 is fixed to the substrate 34, and further fixed to the element 36 to be cooled.

The cooling device 42 has the fins 90. Since the fins 90 increase an area where the cooling device 42 radiates heat to the outside, the refrigerant RF in the gas phase may be efficiently condensed and liquefied inside the container 44 as compared with a structure without the fins 90.

The container 44 has the injection hole 92. Through the injection hole 92, the refrigerant RF may be easily injected into the inside of the container 44 through the injection pipe 96. Then, by filling the injection pipe 96 with the plug 94, a structure may be achieved in which the injection hole 92 is sealed with the plug 94, and the refrigerant RF is sealed inside the container 44.

Next, a second embodiment will be described. In the second embodiment, elements, members, and the like similar to those in the first embodiment are denoted by the same reference signs as those in the first embodiment, and detailed description thereof will be omitted. Furthermore, since an overall structure of a cooling device 242 of the second embodiment is similar to that of the cooling device 42 of the first embodiment, illustration thereof is omitted.

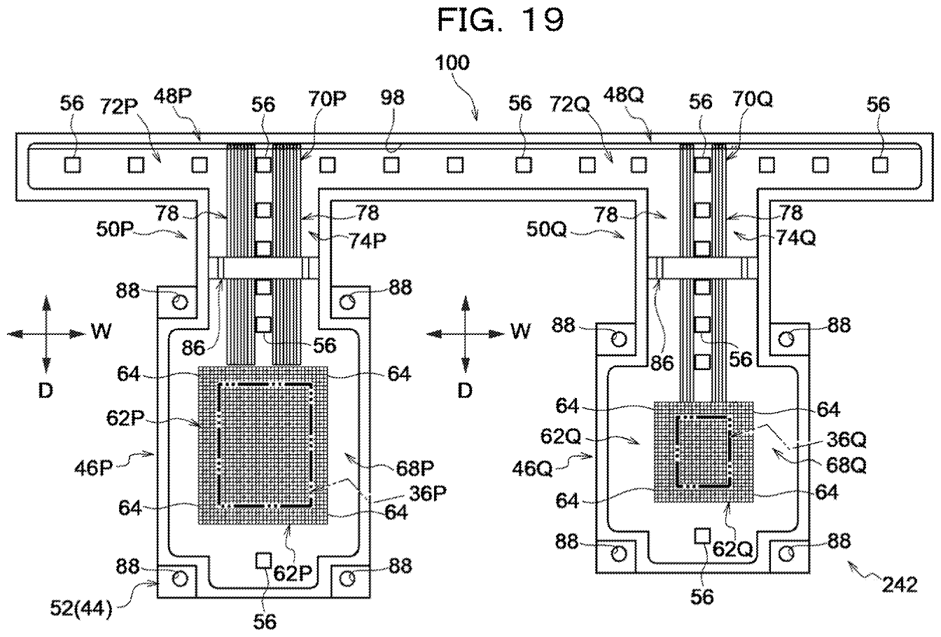

In the cooling device 242 of the second embodiment, as illustrated in FIG. 19, different types of elements are used for an element 36P and an element 36Q. In the example illustrated in FIG. 19, the element 36P is larger than the element 36Q in size and has a larger maximum amount of heat generation.

In addition, in the cooling device 242 of the second embodiment, a heat reception unit 46P and an evaporation unit 62P corresponding to the element 36P are larger than a heat reception unit 46Q and an evaporation unit 62Q corresponding to the element 36Q in size. Moreover, in a transport unit 70P corresponding to the element 36P, the number of transport pipes 78 is larger than that in a transport unit 70Q corresponding to the element 36Q.

Also in the cooling device 242 of the second embodiment having such a structure, it is possible to reliably cool these elements 36P and 36Q according to the amounts of heat generation of the elements 36P and 36Q.

Here, for example, a structure may also be adopted in which a cooling device having a sufficient cooling capacity for each element 36 is provided so that, when a plurality of elements 36 having different amounts of heat generation is cooled, each element 36 may be cooled even when the element 36 generates heat at the maximum amount of heat generation. However, the cooling device corresponding to the maximum amount of heat generation of each element 36 causes an increase in size of the cooling device. For example, in the example illustrated in FIG. 19, the element 36Q may be mounted close to the element 36P for a purpose of maintaining good communication between the element 36P and the element 36Q, or the like. When the element 36P is arranged close to the element 36Q in this way, the element 36Q is likely to receive heat of the element 36P. Moreover, a fixture or the like for fixing the element 36Q to a substrate may also obstruct a flow of cooling air toward fins 90. When the cooling device for cooling the element 36Q is made larger in size in order to avoid these inconveniences, as a result, mounting density of various mounting parts such as the elements 36P and 36Q may decrease or an operation may become unstable.

On the other hand, in the cooling device 242 of the second embodiment, the sizes of the evaporation units 62P and 62Q and the number of transport pipes 78 of the transport units 70P and 70Q are set according to the difference in the maximum amounts of heat generation of the elements 36P and 36Q. In addition, two condensation units 72P and 72Q are shared as a cooling structure for the elements 36P and 36Q, and a refrigerant RF may move between the condensation units 72P and 72Q. With this configuration, it is possible to achieve an integrated cooling structure in which a cooling capacity for each of the elements 36P and 36Q is appropriately distributed according to the elements 36P and 36Q having different maximum amounts of heat generation.

In addition, also in the cooling device 242 of the second embodiment, by arranging the fins 90 of the heat radiation units 48P and 48Q at positions where cooling air from the fan is received with high efficiency, it is possible to more highly exhibit the cooling capacity of the cooling device 42 while making the heat radiation units 48P and 48Q smaller in size.

Next, a third embodiment will be described. In the third embodiment, elements, members, and the like similar to those in the first embodiment are denoted by the same reference signs as those in the first embodiment, and detailed description thereof will be omitted. Furthermore, since an overall structure of a cooling device 342 of the second embodiment is similar to that of the cooling device 42 of the first embodiment, illustration thereof is omitted.

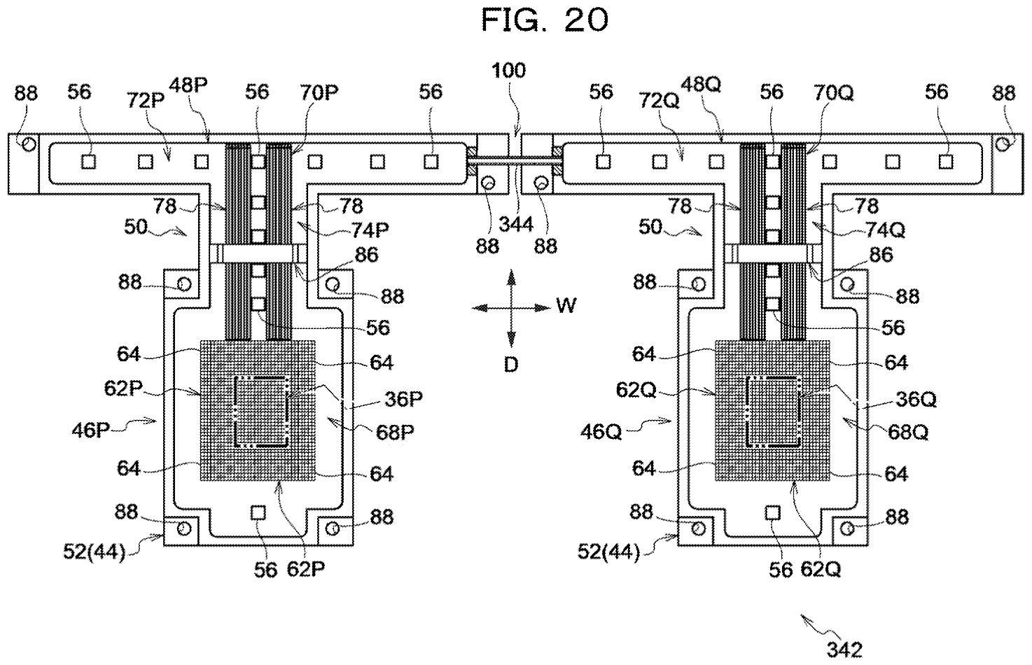

In the cooling device 342 of the third embodiment, as illustrated in FIG. 20, two condensation units 72P and 72Q are independently formed. In addition, a structure having a communication pipe 344 as a movement portion 100 between the condensation units 72P and 72Q is adopted. Note that, in the example illustrated in FIG. 20, the movement groove 98 of the first embodiment (see FIG. 4) is not formed, but the movement groove 98 may be formed in each of the condensation units 72P and 72Q.

In the third embodiment, an inner diameter of the communication pipe 344 is set to an inner diameter that allows, by surface tension acting on a refrigerant RF in a liquid phase, the refrigerant RF to move in a width direction and that is larger than an inner diameter N1 of a transport pipe 78.

Also in the cooling device 342 of the third embodiment having such a structure, since the condensation units 72P and 72Q are communicated with each other by the communication pipe 344, it is possible to move the refrigerant RF in the liquid phase between the condensation units 72P and 72Q through the communication pipe 344. The refrigerant RF in the liquid phase moves between the condensation units 72P and 72Q. With this configuration, a structure is achieved in which more refrigerant RF is supplied to the evaporation unit 62 corresponding to one of the elements 36P and 36Q having a relatively larger amount of heat generation, and cooling is efficiently performed.

For example, in the cooling device 342 of the third embodiment, since the communication pipe 344 communicates the two condensation units 72P and 72Q with each other to make these condensation units 72P and 72Q independent, there is a high degree of freedom in each shape, size, mounting position, and the like.

On the other hand, in the structure in which the two condensation units 72P and 72Q are integrated like the cooling device 42 of the first embodiment, the top plates of the condensation units 72P and 72Q are continuous. Thus, by installing the fins 90 in this continuous portion as well, a large installation area of the fins 90 may be secured.

Note that, it is also possible to adopt, in the cooling device 242 corresponding to the difference in the amount of heat generation of the elements 36P and 36Q as in the second embodiment, a structure in which the two condensation units 72P and 72Q are independent and these condensation units 72P and 72Q are communicated with each other by the communication pipe 344 as in the third embodiment.

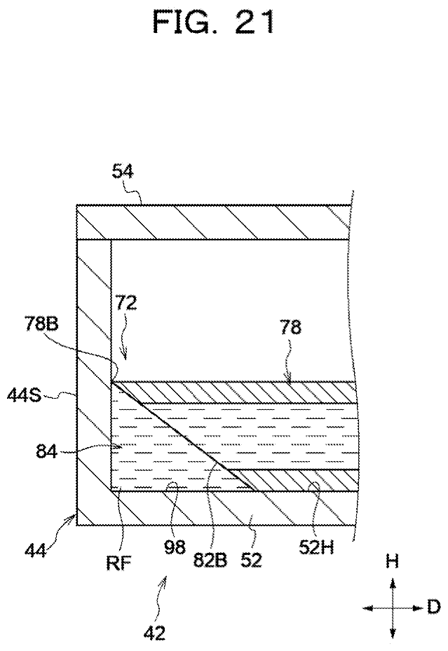

In each of the embodiments described above, the structure of the transport unit 70 is not limited to that described above. As an example, in the structure illustrated in FIG. 8A, the second inclined portion 82B faces diagonally upward, but the second inclined portion 82B may face diagonally downward as in a modification illustrated in FIG. 21, for example. At the second inclined portion 82B facing diagonally downward, the refrigerant RF in the liquid phase may easily flow into the inside of the transport pipe 78.

Furthermore, in each of the embodiments described above, the structure in which a gap is provided between the transport pipe 78 and the evaporation unit 62 is also not limited to that described above.

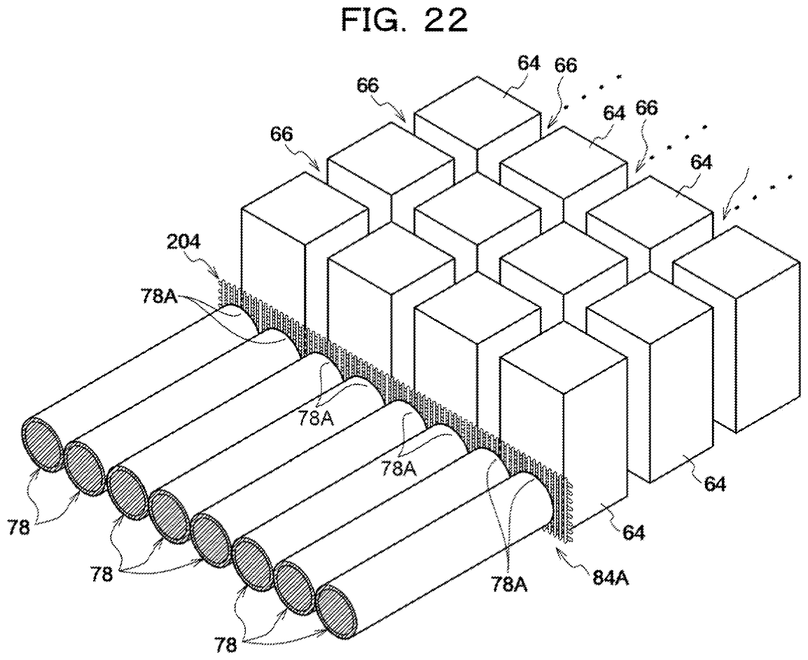

In a first modification illustrated in FIG. 22, as an example of the gap portion, a net member 204 separate from the transport pipe 78 and the evaporation unit 62 is provided. The net member 204 is arranged between the transport pipe 78 and the evaporation unit 62, with one surface in contact with the transport pipe 78 and the other surface in contact with the evaporation unit 62. Note that, in the cooling device 42 of the second embodiment, the inclined portion 82A of the first embodiment (see FIG. 9) is not formed at the one end portion 78A of the transport pipe 78, and the one end portion 78A is orthogonal to the longitudinal direction of the transport pipe 78.

The net member 204 is a member capable of moving fluid in the thickness direction (arrow T direction), and the net member 204 forms the gap 84A between the transport pipe 78 and the evaporation unit 62. Thus, the one end portion 78A of the transport pipe 78 is not blocked by the evaporation unit 62, and the flow path of the refrigerant RF from the one end portion 78A toward the evaporation unit 62 is secured. For example, also in the structure illustrated in FIG. 14, the structure is achieved that facilitates movement of the refrigerant RF in the liquid phase from the transport pipe 78 to the evaporation unit 62.

In the first modification illustrated in FIG. 22, the net member 204 as an example of the gap portion is separate from the transport pipe 78 and the evaporation unit 62. Thus, the net member 204 does not affect the shape of the transport pipe 78 or the evaporation unit 62. For example, it is not needed to process the one end portion 78A of the transport pipe 78, and the structure may be simplified.

The net member 204 is arranged between the transport pipe 78 and the evaporation unit 62, and is in contact with both of them. With this configuration, a relative position between the transport pipe 78 and the evaporation unit 62 is maintained, so that the state where the gap 84A is formed may also be maintained.

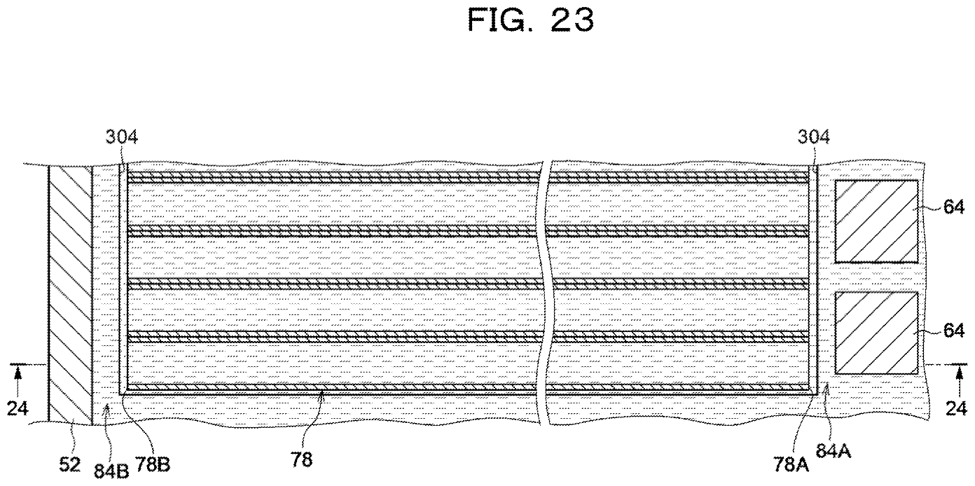

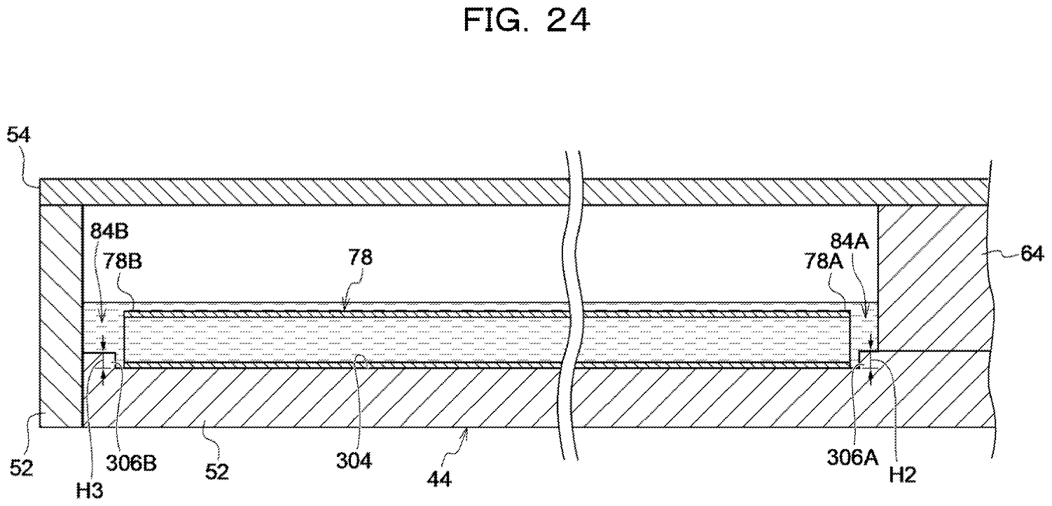

Furthermore, as the structure in which a gap is provided between the transport pipe 78 and the evaporation unit 62, a second modification illustrated in FIGS. 23 and 24 may be applied.

In the second modification illustrated in FIGS. 23 and 24, the bottom plate 52 is provided with a recess 304. The recess 304 has a shape capable of accommodating a lower portion of each transport pipe 78. In addition, as a part of the bottom plate 52, a wall portion 306A is provided between the recess 304 and the evaporation unit 62. Furthermore, as a part of the bottom plate 52, a second wall portion 306B is provided between the recess 304 and the side wall 44S of the container 44. Substantially, the wall portion 306A and the second wall portion 306B are portions of the bottom plate 52 where the recess 304 is not provided.

The wall portion 306A faces the one end portion 78A of the transport pipe 78, and is set to a height H2 that does not obstruct a substantial flow of the refrigerant RF in an inner peripheral portion of the transport pipe 78. In addition, the wall portion 306A forms the gap 84A between the one end portion 78A of the transport pipe 78 and the condensation unit 72.

In the second modification, the wall portion 306A forms the gap 84A between the transport pipe 78 and the evaporation unit 62. Thus, the one end portion 78A of the transport pipe 78 is not blocked by the evaporation unit 62, and the flow path of the refrigerant RF from the one end portion 78A toward the evaporation unit 62 is secured. For example, also in the second modification, the structure is achieved that facilitates movement of the refrigerant RF in the liquid phase from the transport pipe 78 to the evaporation unit 62.

The second wall portion 306B faces the another end portion 78B of the transport pipe, and is set to a height H3 that does not obstruct the substantial flow of the refrigerant RF in the inner peripheral portion of the transport pipe 78. In addition, the second wall portion 306B forms the second gap 84B between the another end portion 78B of the transport pipe 78 and the side wall 44S of the container 44. For example, in the third embodiment, the second wall portion 306B is an example of the second gap portion. Note that, since the height H2 of the wall portion 306A and the height H3 of the second wall portion 306B both correspond to the depth in the recess 304, the height H2 of the wall portion 306A and the height H3 of the second wall portion 306B are equal to each other.

In the second modification, the wall portion 306A as an example of the gap portion is provided in the container 44. Since the gap portion is not provided in the transport pipe 78, it is not needed to process the one end portion 78A of the transport pipe 78, and the structure may be simplified. Furthermore, since it is not needed to provide a new member as the gap portion, the number of parts does not increase.

In the second modification, the container 44 is provided with the recess 304. As a portion of the transport pipe 78 facing the one end portion 78A, a structure having the gap portion may be achieved with a simple structure.

Furthermore, since the transport pipe 78 is accommodated in the recess 304 of the bottom plate 52, a space between the transport pipe 78 and the top plate 54 may be secured wider as compared with a structure without the recess 304.

In the above, in the evaporation unit 62, the column member 64 is mentioned as a member for forming the groove 66, but the member forming the groove 66 is not limited to the column member. For example, a structure may be adopted in which a plurality of wall members extending in the depth direction is arranged side by side at regular intervals in the width direction. In the structure having the wall members, a groove extending in the depth direction is formed between the wall members.

While the embodiments of the technology disclosed in the present application have been described thus far, the technology disclosed in the present application is not limited to the embodiments described above and it will be understood that, in addition to the embodiments described above, various modifications may be made and implemented within the spirit and scope of the technology.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A cooling device comprising:
a container in which a refrigerant is sealed;
a plurality of evaporation structures that evaporate the refrigerant in a liquid phase inside the container by heat reception;
a plurality of condensation structures each of which is provided in corresponding one of the plurality of evaporation units and which condenses the refrigerant in a gas phase inside the container by heat radiation;
a transport structure that transports the refrigerant in the liquid phase from the condensation units to the evaporation units by surface tension; and
a movement portion that communicates the plurality of condensation units such that the refrigerant in the liquid phase is movable between the plurality of condensation structures.

2. The cooling device according to claim 1, wherein
the movement portion includes
a movement groove that integrates the plurality of condensation structures, is continuously provided in the integrated condensation units to allow the refrigerant in the liquid phase to move by surface tension, and has a flow path cross-sectional area larger than a flow path cross-sectional area of the transport structure.

3. The cooling device according to claim 1, wherein the movement portion is a communication pipe that is hung between the plurality of condensation structures to communicate the condensation structures with each other, and that has a flow path cross-sectional area larger than a flow path cross-sectional area of the transport structure.

4. The cooling device according to claim 1, wherein the plurality of condensation structures is arranged linearly.

5. The cooling device according to claim 4, wherein the plurality of evaporation structures is arranged on the same side as the plurality of condensation structures arranged linearly.
